(19) United States
(12) Patent Application Publication
(10) Pub. No.: US 2010/0112816 A1
(43) Pub. Date: May 6, 2010

(54) METHOD OF REDUCING NON-UNIFORMITIES DURING CHEMICAL MECHANICAL POLISHING OF MICROSTRUCTURE DEVICES BY USING CMP PADS IN A GLAZED MODE

(76) Inventors: Gerd Marxsen, Radebeul (DE); Jens Heinrich, Wachau (DE); Jana Schlott, Wachau (DE)

Correspondence Address: WILLIAMS, MORGAN & AMERSON, 10333 RICHMOND, SUITE 1100, HOUSTON, TX, 77042, US

(21) Appl. No.: 12/575,996

(22) Filed: Oct. 8, 2009

(30) Foreign Application Priority Data
Oct. 31, 2008 (DE) 10 2008 054 074.9

(51) Int. Cl. H01L 21/306; B24B 1/00

(52) U.S. Cl. 438/692; 451/57; 257/E21.23

(57) ABSTRACT

In sophisticated CMP recipes, the material removal may be accomplished on the basis of a chemically reactive slurry material and a reduced down force, wherein the surface topography of a finally obtained material layer may be enhanced by using, at least in a final phase, a glazed state of the polishing pad.

### BACKGROUND OF THE INVENTION

1. Field of the Invention

The present disclosure generally relates to the field of fabricating microstructure devices, such as integrated circuits, and, more particularly, to the planarization of a metallization layer and/or the removal of excess metal from a dielectric layer.

2. Description of the Related Art

In manufacturing microstructures, such as integrated circuits, various material layers are deposited on a substrate and are patterned by lithography, such as photolithography, and etch processes and the like to provide a large number of individual features, such as circuit elements in the form of transistors, capacitors, resistors, interconnect structures and the like. Due to the continuous reduction of feature sizes of the individual structure elements, sophisticated lithography and etch techniques have been developed that allow the resolution of critical dimensions, i.e., of minimum feature sizes, well beyond the wavelength of the radiation used for transferring images from a reticle to a mask layer that is used in subsequent etching processes. Since these sophisticated imaging techniques are quite sensitive to any underlying material layers and to the surface topography, it is frequently necessary to planarize the respective device levels formed above the substrate to provide a substantially planar surface for the application of further material layers to be patterned. This holds especially true for so-called metallization layers required in integrated circuits or other microstructure devices comprising a plurality of electric elements to electrically connect the individual circuit elements. Depending on the feature sizes of the circuit elements and the number thereof, typically a plurality of metallization layers, stacked on top of each other and electrically connected by so-called vias, are required for providing the complex functionality of modern integrated circuits.

It has therefore become standard practice in forming stacked metallization layers to planarize the current device level of the substrate prior to forming a subsequent metallization layer. Chemical mechanical polishing (CMP) or generally planarization has proven to be a viable process technique for this purpose. In chemically mechanically polishing a substrate surface, in addition to the mechanical removal of the material, a slurry is supplied, typically containing one or more chemical reagents that react with the material or materials on the surface, wherein then the reaction products may be more efficiently removed by the mechanical polishing process. In addition to the appropriate selection of the slurry composition, the relative motion between the substrate and a polishing pad, as well as the force with which the substrate is pressed against the polishing pad, are controlled to obtain the desired removal rate.

Recently, chemical mechanical polishing has increasingly gained in importance as aluminum is continuously replaced with copper and other metals or metal alloys of enhanced conductivity in high end integrated circuits exhibiting feature sizes in the deep sub-micron regime. Although copper and alloys thereof exhibit superior characteristics compared to aluminum in terms of conductivity and resistance against electromigration, many problems are involved in processing copper-based materials in a semiconductor facility, one of which resides in the fact that copper may not be very efficiently deposited in large amounts with well-established deposition techniques such as chemical vapor deposition (CVD) and sputter deposition. Moreover, copper may not be efficiently patterned by conventional anisotropic etch techniques. Therefore, instead of applying copper or copper alloys as a blanket layer and patterning metal lines, the so-called damascene or in-laid approach has become a standard process technique in forming metallization layers comprised of copper.

In the damascene technique, trenches and vias are formed in a dielectric layer and subsequently the metal is filled into the trenches and vias, wherein a certain amount of over-filling has to be provided. Prior to depositing the metal, usually by performing a plating process, such as electroplating or electroless plating, a barrier layer is formed in the trench to minimize out-diffusion of copper or other highly diffusive metal compounds into the adjacent dielectric. Thereafter, a thin seed layer for electroplating strategies or any other activation material is usually applied using appropriate deposition techniques, such as sputter deposition, CVD, atomic layer deposition (ALD), electroless deposition and the like, to facilitate the subsequent plating process of the bulk metal material. After the deposition of the metal, the excess metal, including the thin barrier layer and the seed layer, has to be reliably removed in order to obtain metal trenches and vias that are electrically insulated from each other. The excess material is frequently removed by a process sequence including chemical mechanical polishing. The respective wet chemical deposition process may require sophisticated recipes in order to reliably fill trenches and vias of different aspect ratios in a substantially void-free manner. Moreover, the deposition behavior may depend on the local pattern geometry, that is, densely packed areas may result in a different local deposition rate in areas outside the trenches and vias compared to areas having isolated metal regions. Thus, after the wet chemical deposition process, a pronounced surface topography may be encountered. Due to the complex surface topography and the plurality of different materials that may be present at the same time, at least during a final phase of the polishing process, a sophisticated operation mode may be required for removing the essential amount of the metal in a first polishing period and removing metal, barrier material and to a certain amount the dielectric during a subsequent phase of the polishing process.

The polishing process may therefore be carried out in several steps or operation modes, wherein the uniformity of each phase may have a significant influence on the overall process uniformity. Thus, different chemistries in the slurries as well as different parameter settings for the speed of the relative motion and/or the down force applied to the substrate during these different polishing phases may be required. In sophisticated process regimes, the slurries used may have a highly efficient chemical component in order to obtain the desired high removal rate based on the chemical reaction, while abrasives are also added to the slurry to adjust the mechanical removal rate. In the final phase, the removal is more complex as usually two or more materials have to be polished at the same time, i.e., the metal, the barrier material and the dielectric. Moreover, a certain amount of “overpolish” has to be applied in an attempt to remove substantially all of the conductive material on surface portions of the dielectric material to minimize leakage currents or shorts between adjacent metal lines. Completely removing the conductive material from a substrate having a diameter of 200 or 300 mm is, however, a challenging task and usually leads to a certain amount of dishing and erosion of the metallization structures.

In particular, if a plurality of sophisticated metallization layers are stacked so as to form the metallization system of an advanced integrated circuit, typically, highly sensitive dielectric materials having a reduced permittivity, and thus also a significantly reduced mechanical stability, may result in a highly sensitive layer stack, which may require significantly reduced down forces during the polishing process so as to not unduly cause damage in the metallization system. However, in view of maintaining a desired high throughput during the CMP process, the reduction in removal rate caused by reduced down force may typically be compensated for by using a chemically reactive slurry material so that the chemical removal component may be significantly increased. Thus, during sophisticated CMP recipes, a plurality of complex interrelated factors may determine the finally obtained removal rate and also the resulting surface topography across individual substrates and also across a plurality of substrates processed by using the same CMP recipe. That is, during the removal process, the chemically reactive slurry may be supplied and may be distributed with the relative motion between the polishing pad and the surface to be polished by the pores that are typically provided in the polishing pad. For example, well-established polishing materials may comprise a polyurethane surface including pores and grooves that may provide an efficient distribution of the slurry material. Upon contact of the polishing pad and the surface to be polished, abrasive particles, which may be contained in the slurry material, and corresponding polish byproducts may increasingly accumulate in the pores of the polishing pad, thereby reducing the capability of efficiently distributing slurry. Furthermore, the accumulation of particles and polishing byproducts may increasingly result in a “hardening” of the surface, which is typically referred to as glazing, which may result in a significant drop of removal rate due to a reduced degree of surface roughness of the polishing pad in combination with a reduced capability of distributing the slurry material. Due to the increasing glazing condition of the polishing pad, typically the surface thereof is “conditioned” or reworked on a regular basis and/or during the actual polishing process, for instance by contacting the polishing pad with a conditioning surface, which may include hard material, such as diamond and the like, in order to create corresponding “channels” in the clogged pores of the polishing pad. Thus, the glazing of the polishing pad may be efficiently prevented, thereby maintaining removal rate at a high level while also stabilizing the degree of across-substrate non-uniformities of the polishing process.

Consequently in sophisticated polishing recipes using slurry materials of increased chemical reactivity, the mechanical and chemical interaction of the polishing pad and the slurry, respectively, with a substrate surface in combination with the complex condition effect used to maintain a desired high polishing rate may thus result in tightly set process windows for CMP processes formed on the basis of sophisticated materials, such as metallization layers of advanced integrated circuits.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention relates to techniques for planarizing or generally removing material from a layer system of a microstructure device at reduced down forces during the polishing process, while nevertheless providing a desired removal rate in combination with enhanced process control with respect to uniformity of the resulting surface topography. For this purpose, the polishing process may be performed on the basis of a polishing pad having a state of reduced surface roughness, which may thus contribute to enhanced overall process uniformity in combination with highly chemically reactive slurry materials. The reduced surface roughness of the polishing pad may be established by controlling the degree of conditioning of the polishing pad such that a moderately high degree of glazing may intentionally be maintained so as to adapt the mechanical removal component for the benefit of enhanced surface topography. Consequently, sophisticated layer stacks, such as metallization systems including low-k dielectric materials in combination with a soft metal, such as copper, may be efficiently planarized on the basis of reduced down forces, while also maintaining the overall removal rate at a desired high value due to the usage of a chemically reactive slurry material. On the other hand, due to the increased degree of glazing of the polishing pad, which may be maintained at least at a final phase of the polishing process, i.e., during the exposure of a dielectric material and a corresponding overpolish time, which may be required so as to reliably electrically insulate respective metal regions from each other, the reduced surface roughness of the glazed polishing pad may provide a corresponding reduction and thus adaptation of the overall removal rate. Hence, in this critical phase of the polishing process, metal may still be removed from dielectric surface portions to be cleared, while undue dishing, i.e., undue recessing metal in the metal regions, may be reduced, which may translate into enhanced performance of the corresponding metal regions since generally an increased cross-sectional area may be maintained.

One illustrative method disclosed herein relates to planarizing a metal-containing layer that is formed above a substrate of a semiconductor device. The method comprises removing material of the metal by performing a polishing process by establishing a relative motion between a polishing pad and the substrate. Moreover, the method comprises supplying chemically reactive slurry to enhance a removal rate for the metal. Finally, the method comprises controlling the removal rate by conditioning the polishing pad so as to maintain a surface of the polishing pad in a glazed state, at least in a final phase of the polishing process.

A further illustrative method disclosed herein comprises removing a metal material from a dielectric layer of a microstructure device by performing a first polishing process in the presence of a slurry that chemically reacts with the metal material, wherein the first polishing process has a first removal rate for the metal material. The method further comprises controlling a degree of conditioning of a polishing pad in a second polishing process so as to maintain the polishing pad in a glazed state that results in a second removal rate that is approximately 70 percent or less of the first removal rate of the first polishing process. Finally, the method comprises performing the second polishing process on the basis of a glazed state so as to expose surface portions of the dielectric layer.

A still further illustrative method disclosed herein relates to the planarization of a metallization layer of a microstructure device that is formed above a substrate. The method comprises removing excess metal of the metallization layer in a first polishing phase of a polishing process, wherein the first polishing phase is performed on the basis of a predetermined relative speed between a polishing pad and the substrate and on the basis of a predetermined down force applied to the substrate. Furthermore, the method comprises exposing a dielectric material of the metallization layer in a second phase of the polishing process. Finally, the method comprises maintaining a degree of pad glazing at approximately 15 percent or more, at least during the second polishing phase.

### BRIEF DESCRIPTION OF THE DRAWINGS

The disclosure may be understood by reference to the following description taken in conjunction with the accompanying drawings, in which like reference numerals identify like elements, and in which:

FIGS. 1a and 1b schematically illustrate cross-sectional views of a microstructure device in various phases of a polishing process so as to planarize the metallization stack, wherein, at least in a final phase of the polishing process, a glazed state of the polishing pad may be used, in accordance with illustrative embodiments;

FIG. 1c schematically illustrates a diagram illustrating the difference in removal rates and a degree of dishing for a non-glazed state and a glazed state as may be used, at least in the final phase of the polishing process, according to illustrative embodiments;

FIG. 1d schematically illustrates a cross-sectional view of a surface topography of a polishing pad in a glazed state, according to illustrative embodiments; and

FIG. 1e schematically illustrates a polishing system in which the conditioning of a polishing pad may be controlled so as to maintain a desired glazed state, thereby reducing surface topography of the polishing pad, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides techniques for planarizing sophisticated material stacks of microstructure devices, such as metallization systems including low-k dielectric materials in combination with highly conductive metals, such as copper, wherein a moderately high removal rate of the overall planarization process may be established while not unduly exerting mechanical forces to the material layer stack. For this purpose, chemically reactive slurry materials may be used to provide the possibility of reducing the down force during the polishing process in view of reducing the mechanical stress components during the polishing process, wherein additionally, at least in a final phase of the polishing process, i.e., during the exposure of a corresponding dielectric material, a reduced degree of surface roughness of the polishing pad may be maintained in order to avoid undue surface irregularities in the dielectric material and any exposed metal regions. The reduced surface roughness of the polishing pad may be established by maintaining a certain degree of pad glazing, which, according to conventional strategies, is considered a highly inappropriate condition of a polishing pad. In the present disclosure, however, the degree of glazing is appropriately controlled by correspondingly adjusting the degree of pad conditioning in order to provide the desired low surface roughness of the polishing pad while nevertheless maintaining a high degree of process uniformity.

It should be appreciated that, in the context of the present disclosure, a glazed state of a polishing pad may be understood such that, for a given initial configuration of the polishing pad, a certain percentage of “saturation,” and thus “clogging” the corresponding pores in the polishing pad, may be considered as a measure for the degree of glazing. For instance, when 15 percent or more of the initially provided pores are filled and thus may remain functional with respect to distributing slurry, the corresponding polishing pad may be considered as being in a glazed state. On the other hand, a non-glazed state may be considered as a state in which the corresponding ability of accumulating slurry, particles and polishing byproducts may be at approximately 40 percent or less compared to the initial capability of the polishing pad, wherein it should be understood that the initial capabilities refer to the state after polishing an appropriate number of dummy substrates. From a different point of view, a glazed state is to be considered as a state in which, for a given polishing recipe, i.e., for a given slurry material and a corresponding parameter set including the relative speed and the down force, a drop in removal rate of at least approximately 30 percent compared to the initial removal rate of the polishing pad is achieved.

Consequently, by using a glazed condition of the polishing pad in a highly controlled manner, i.e., by appropriately controlling the conditioning of the polishing pad so as to maintain a substantially constant degree of glazing, the surface topography of sophisticated metallization layers may be enhanced since, for instance, in the final phase of the polishing process, enhanced polishing conditions may be established. That is, during the final phase, different materials may have to concurrently polished, i.e., any metal residues of the typically soft highly conductive metal, such as copper, any conductive barrier materials and also dielectric material that may increasingly be exposed during this phase of the polishing process. Consequently, by applying the polishing pad in a glazed state, the general removal rate may be reduced while nevertheless reliably clearing the surface of the dielectric material, wherein additionally an enhanced degree of controllability of this phase of the removal process may be achieved. At the same time, a degree of dishing is also significantly reduced, thereby not unduly reducing the cross-sectional areas of the metal lines, which may thus contribute to an overall increased performance of the corresponding metallization layer.

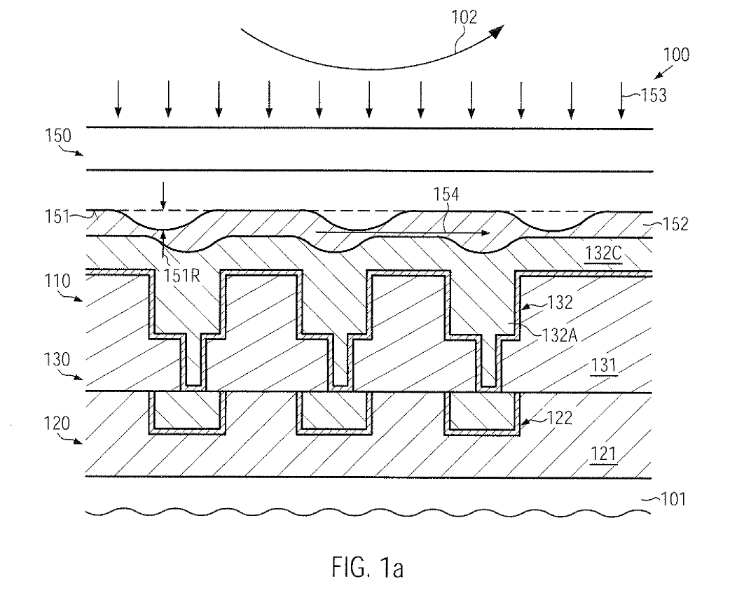

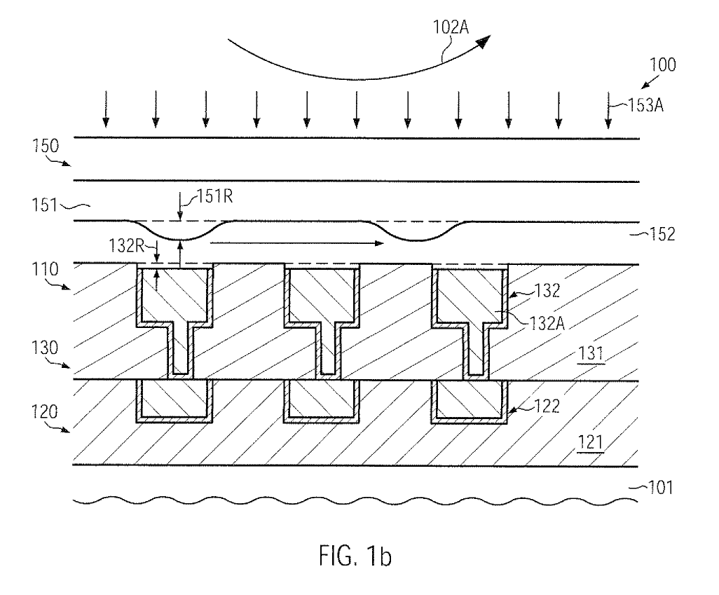

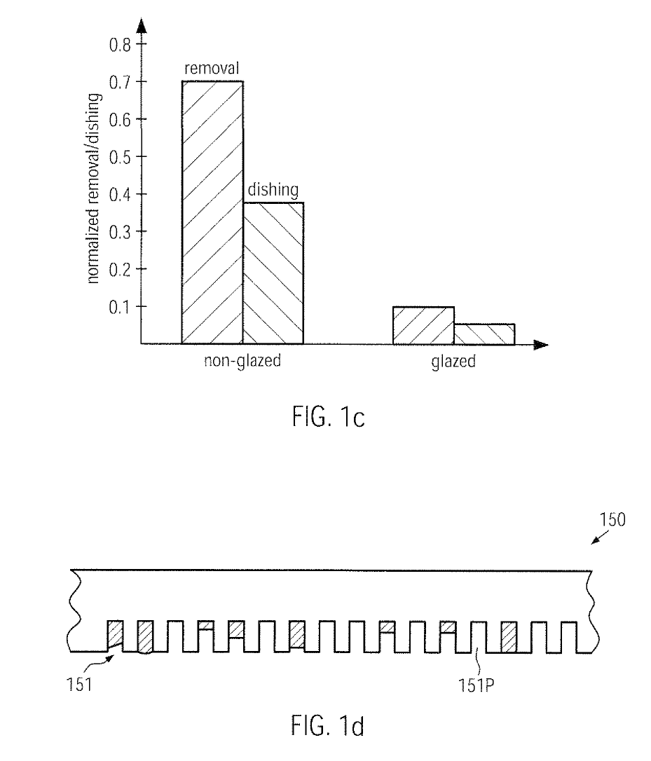

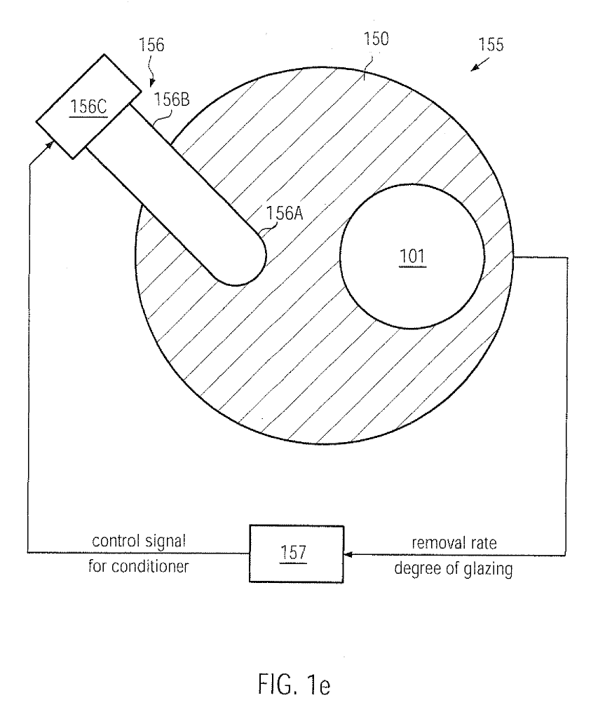

FIG. 1a schematically illustrates a cross-sectional view of a microstructure device 100 comprising a substrate 101 above which may be formed a metallization system 110. For example, the microstructure device 100 may represent an integrated circuit including a complex circuit layout that is realized on the basis of circuit elements formed in and above the substrate 101. For example, the circuit elements may include transistor elements having critical dimensions of 50 nm and less. The complex circuit layout may require a corresponding number of metallization layers 120, 130 in the metallization system 110 in order to establish the required electrical connections. As previously discussed, in some illustrative embodiments, at least some of the metallization layers 120, 130 may comprise sophisticated sensitive dielectric materials in combination with highly conductive metals, such as copper. For example, the metallization layer 120 may comprise a dielectric material 121, which may include a low-k dielectric material or an ultra low-k (ULK) material, which may be provided in a more or less porous state, depending on the overall device requirements. It should be appreciated that a low-k dielectric material is to be understood as a material having a dielectric constant of 3.0 and less. Moreover, metal regions 122, such as metal lines, may be embedded in the dielectric material 121. Similarly, the metallization layer 130 may comprise a dielectric material 131, which may include sophisticated and sensitive low-k dielectric materials and the like. Moreover, metal regions 132, for instance in the form of metal lines and the like, may be embedded in the dielectric material 131, possibly in combination with a conductive barrier material, such as tantalum, tantalum nitride, titanium, titanium nitride or any other appropriate materials or compositions, which may provide enhanced adhesion and confinement of a highly conductive metal 132A, such as copper. In the manufacturing stage shown, a layer of excess metal 132C may be formed above the metallization layer 130 and may have to be removed so as to obtain a desired planar surface topography, as may be required for the further processing of the device 100, for instance in view of performing further sophisticated lithography steps for the formation of additional device levels.

The microstructure device 100 may be formed on the basis of well-established process techniques, such as damascene or inlaid strategies, in which the dielectric materials of the corresponding metallization layers 120, 130 may be deposited first and may then be patterned so as to receive corresponding openings, which are subsequently filled by the barrier material 132A and the metal 132. During the corresponding complex manufacturing sequence, also the excess material 132C may have to be provided so as to ensure a reliable fill behavior. Thus, the excess material 132C and also the conductive barrier material 132A formed on horizontal device portions has to be removed, which is typically accomplished by a planarization process 102, which may include a CMP process. For example, the planarization process 102 may include an electrochemical etch process at an initial phase and may thereafter be continued on the basis of a CMP process. During the CMP process, the metallization layer 130, i.e., in the initial phase, the excess metal 132C may be brought into contact with a polishing pad 150 which may comprise a polishing surface 151. As previously explained, the surface 151 may be comprised of well-established materials such as polyurethane, including a plurality of micro pores that may have a depth of several micrometers and more and which may have a lateral size of several micrometers on average. Furthermore, during the process 102, a slurry material 152 may be provided which may have a moderately high etch effect with respect to the material 132C in order to enhance the chemical component of the CMP process. For instance, respective slurry materials having an acid that may be appropriate for appropriately reacting with the material 132C, for instance by converting the same into an oxide material and the like, may be used. It should be appreciated that a plurality of chemically reactive slurry materials are available in the art and may be used for the process 102. Furthermore, a down force 153 may be applied to the polishing pad 150 so as to act on the device 100, wherein the down force 153 may typically be selected so as to generally comply with the mechanical characteristics of the metallization system 110. That is, as previously discussed, sensitive low-k dielectric materials may have a significantly reduced mechanical strength compared to conventional dielectrics, such as silicon dioxide, silicon nitride and the like, thereby also requiring a corresponding adaptation of the down force 153 in order to reduce stress-related degradation of the metallization system 110 and also reduce yield losses caused by any failures during the further manufacturing processes. Moreover, during the process 102, a relative motion 154 between the polishing pad 150 and the device 100 may be established, thereby also efficiently distributing the slurry material 152 and providing, in combination with the down force 153, a corresponding physical component in removing material of the layer 132C.

In some illustrative embodiments, the down force 153 and the relative motion 154 may be maintained constant during the entire polishing process 102, thereby enhancing overall controllability of the process 102. Furthermore, as previously indicated, due to the increased chemical etch rate of the slurry material 152, the surface roughness of the polishing pad 150, i.e., of the surface 151 thereof, as indicated by 151R, may be maintained at a specified level that may be significantly less compared to the surface roughness corresponding to initial condition of the polishing pad 150, which may also correspond to a non-glazed state, as previously defined. Thus, in some illustrative embodiments, the degree of glazing may intentionally be increased, compared to conventional concepts, thereby also reducing the surface roughness 151R. Consequently, a significant fraction of the overall removal rate may be contributed by the chemical behavior of the slurry material 152, even if the down force 153 is reduced to a level that is compatible with the mechanical characteristics of the system 110. On the other hand, the pad asperity is reduced, thereby nevertheless providing enhanced surface topography during the removal process 102.

FIG. 1b schematically illustrates the microstructure device 100 in an advanced stage. That is, the device 100 is subjected to a polishing process 102A during which a dielectric material 131 of the metallization layer 130 may be increasingly exposed so as to finally obtain the metal regions 132 as isolated entities. In one illustrative embodiment, the polishing process 102A may represent a final phase of the polishing process 102 of FIG. 1a, wherein, in some embodiments, the same process parameters with respect to the down force 153 and the relative speed 154 may be applied. Furthermore, in one embodiment, the degree of glazing may also be maintained substantially constant or may at least be controlled on the basis of the same process parameter values as may be used during the process 102 of FIG. 1a. Consequently, as previously explained, the excess material 132C (FIG. 1a) may be efficiently removed while also during the final phase of the polishing and the increasing exposure of the dielectric material 131, the generally reduced surface roughness may result in a reduced degree of dishing. For example, as illustrated, the degree of material removal 132R in the metal regions 132 may be maintained at a desired low level due to a less pronounced surface roughness of the polishing pad caused by the glazed state of the pad 150.

In other illustrative embodiments, the polishing process 102A may represent a phase in which different process parameters may be used so as to further reduce the surface roughness to a value 151R, thereby even further enhancing the resulting surface topography of the metallization layer 130 upon exposing the dielectric material 131. For example, during the polishing process 102A, a reduced degree of conditioning effect may be applied so as to increase the degree of glazing and thus reduce the surface roughness to the desired value 151R. In some illustrative embodiments, the processes 102 of FIG. 1a and the polishing process 102A may be performed on the basis of different CMP chambers, i.e., different polishing pads 150 may be used, each of which may be appropriately conditioned so as to obtain the desired degree of glazing. In some illustrative embodiments, the process 102 of FIG. 1a may be performed, at least for a fraction thereof, on the basis of a substantially non-glazed state of the polishing pad 150 so as to provide an even further increased removal rate. Thereafter, the device 100 may be exposed to the polishing ambient 102A providing a reduced surface roughness 151R and a corresponding glazed state, thereby obtaining the enhanced surface conditions at the final stage of the polishing process 102A.

In still other illustrative embodiments, the polishing process 102A may represent a final phase of a single continuous process in which the degree of conditioning may be reduced so as to further reduce the surface roughness, as indicated by 151R. It should be appreciated that a corresponding process technique may be established in process regimes in which generally the conditioning may be performed concurrently with the polishing process so that, at any appropriate point in time, a reduced conditioning effect may increasingly contribute to an increased degree of glazing so that, upon clearing the dielectric material 131, a desired surface roughness 151R may be obtained.

FIG. 1c schematically illustrates a diagram that may represent the behavior of two polishing processes or phases which may be performed on the basis of a “non-glazed” and “glazed” state, respectively. For example, the vertical axis may represent the normalized removal rate for the material under consideration, for instance the excess metal 132C of FIG. 1a, and also the degree of dishing, i.e., the material removal of the metal lines 132, as indicated by 132R in FIG. 1b. As illustrated, the normalized removal rate for the non-glazed state may substantially correspond to 0.7, while the dishing may be approximately 0.35. On the other hand, the glazed state of the polishing pad may result in a removal rate of 0.1 and a degree of dishing of approximately 0.05. Consequently, by appropriately reducing the removal rate, an enhanced degree of controllability may be accomplished, in particular during the final phase of the polishing process, such as the process 102A of FIG. 1b, so that undue material removal of the dielectric material 131 and thus of the metal regions 132 may be avoided. In addition to providing enhanced controllability, the corresponding surface roughness of the polishing pad may be significantly reduced, thereby also reducing the degree of non-planarity of the resulting surface topography, which may enhance performance of additional process steps, such as lithography steps and the like. As discussed above, at least the process 102A of FIG. 1b may be performed on the basis of the glazed state of the polishing pad, thereby providing the desired enhanced surface topography. Moreover, the process 102 of FIG. 1a may be performed on the basis of a substantially non-glazed state or a glazed state, depending on the overall process strategy.

FIG. 1d schematically illustrates a cross-sectional view of a portion of the polishing pad 150. As illustrated, the polishing surface 151 may comprise a plurality of pores which may typically be conditioned so as to allow efficient distribution of a slurry material and also accommodate particles and aggressive components. However, according to the present disclosure, the pores may intentionally be maintained at a certain state of clogging or glazing so that at least approximately 15 percent of the pores 151P may be filled and closed, thereby providing a reduced overall surface roughness, as previously explained. It should be appreciated that the degree of glazing may be detected on the basis of optical inspection, testing of the hardness of the surface 151 and the like. Furthermore, the degree of glazing may also be identified by determining the removal rate for otherwise constant test parameters.

FIG. 1e schematically illustrates a polishing system 155 which may be configured so as to perform at least the polishing process 102A of FIG. 1b. That is, the system 155 may comprise the polishing pad 150 and a corresponding polishing platen (not shown) that is configured to receive and hold in place the pad 150. Moreover, a corresponding drive assembly may be provided (not shown) that is configured to rotate or otherwise move the polishing pad 150 relative to the substrate 101. For instance, the substrate 101 may be received by a corresponding carrier or polishing head, which may also be driven by a corresponding drive assembly (not shown). For example, both the polishing pad 150 and the substrate 101 may be rotated in order to establish the desired relative motion. Furthermore, the system 155 may comprise a conditioning unit 156 including a conditioning arm 156B attached to a drive assembly 156C, which may be configured so as to move the conditioning arm 156B at least across a portion of the polishing pad 150. Moreover, in some illustrative embodiments, a down force of the conditioning arm 156B may also be adjusted on the basis of the drive assembly 156C. The conditioning arm 156B may have attached thereto a conditioning surface 156A which may comprise any appropriate conditioning surface as required for reworking the polishing pad 150. For example, the surface 156A may comprise diamond components and the like so as to “scratch” the polishing pad 150. Moreover, a control unit 157 may be provided and may be operatively connected to the drive assembly 156C in order to supply an appropriate control signal thereto, which in turn may cause the drive assembly 156C to appropriately move the arm 156B. Consequently, based on the control signal supplied by the unit 157, the degree of conditioning of the polishing pad 150 may be adjusted. On the other hand, the control unit 157 may receive process data indicating a momentary degree of glazing of the polishing pad 150. For example, the process data may represent a current removal rate obtained for a given type of slurry and respective process parameters, such as relative speed and down force. In other cases, the corresponding process data may represent a degree of friction between the substrate 101 and the polishing pad 150, as for instance obtained by monitoring the current drawn by an electric motor of the drive assembly and the like. In still other illustrative embodiments, a corresponding process data may be obtained by the conditioning system 156, for instance by measuring the amount of the drive current required for performing a corresponding conditioning activity. Consequently, based on the process data, the control unit 157 may determine a required degree of conditioning so as to maintain the polishing pad 150 in the glazed state, at least during the phase 102A of FIG. 1b. For example, after processing one or more substrates 101, a corresponding re-adjustment of the conditioning effect may be performed on the basis of the control unit 157 and the corresponding process data obtained from the previously processed one or more substrates.

As a result, the present disclosure provides process techniques for planarizing sophisticated material stacks on the basis of a polishing process in which an intentionally established glazed state of the polishing pad may be applied so as to enhance overall controllability and also the resulting surface topography. For this purpose, the degree of conditioning may be appropriately adjusted so as to obtain the desired glazing state, at least at a final phase of the polishing process, so that the reduced surface roughness of a glazed polishing pad may cause a reduced degree of dishing of exposed metal regions. Furthermore, polishing recipes may be used with an appropriately adapted down force while overall removal rate may be maintained at a desired high level by using chemically reactive slurry materials.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method of planarizing a metal-containing layer formed above a substrate of a semiconductor device, the method comprising:
removing material of said metal by performing a polishing process by establishing a relative motion between a polishing pad and said substrate;
supplying a chemically reactive slurry so as to enhance a removal rate for said metal; and
controlling said removal rate by conditioning said polishing pad so as to maintain a surface of said polishing pad in a glazed state at least in a final phase of said polishing process.

2. The method of claim 1, wherein said polishing pad is conditioned so as to maintain said glazed state throughout the entire polishing process.

3. The method of claim 1, wherein said polishing pad is conditioned so as to maintain said glazed state in a final phase of said polishing process.

4. The method of claim 1, further comprising exposing a dielectric material during said polishing process, wherein said dielectric material has embedded therein metal regions comprised of said metal.

5. The method of claim 4, wherein said polishing process comprises a first polishing phase performed on the basis of a first removal rate and a second polishing phase performed on the basis of a second reduced removal rate.

6. The method of claim 5, wherein said first polishing phase is performed by applying an increased degree of conditioning compared to said second polishing phase.

7. The method of claim 5, further comprising removing at least a portion of said metal in said first phase of said polishing process by using a different polishing pad.

8. The method of claim 4, wherein said metal-containing layer is planarized by using said polishing pad as the only polishing pad.

9. The method of claim 1, wherein said metal-containing layer represents a metallization layer of a metallization system of said semiconductor device.

10. The method of claim 9, wherein said metallization system comprises a low-k dielectric material.

11. A method, comprising:
removing a metal material from a dielectric layer of a microstructure device by performing a first polishing process in the presence of a slurry that chemically reacts with said metal material, said first polishing process having a first removal rate for said metal material;
controlling a degree of conditioning of a polishing pad in a second polishing process so as to maintain said polishing pad in a glazed state, said glazed state resulting in a second removal rate that is approximately 70 percent or less of said first removal rate of said first polishing process; and
performing said second polishing process on the basis of said glazed state so as to expose surface portions of said dielectric layer.

12. The method of claim 11, further comprising establishing a non-glazed state of a polishing pad of said first polishing process.

13. The method of claim 11, wherein said first and second polishing processes are performed by using the same polishing pad.

14. The method of claim 11, wherein said metal material comprises copper.

15. The method of claim 14, wherein said dielectric layer comprises a low-k dielectric material.

16. The method of claim 11, wherein said glazed state of said polishing pad is established so as to result in said second removal rate that is approximately 50 percent or less of said first removal rate.

17. The method of claim 11, wherein a value of at least one process parameter is the same in said first and second polishing processes.

18. The method of claim 17, wherein said at least one process parameter is a down force applied during said first and second polishing processes.

19. The method of claim 11, wherein said second polishing process is performed in the presence of said slurry.

20. A method of planarizing a metallization layer of a microstructure device formed above a substrate, the method comprising:
removing excess metal of said metallization layer in a first polishing phase of a polishing process, said first polishing phase being performed on the basis of a predetermined relative speed between a polishing pad and said substrate and a predetermined down force applied to said substrate;
exposing a dielectric material of said metallization layer in a second phase of said polishing process; and
maintaining a degree of pad glazing at approximately 15 percent or more at least during said second polishing phase.

21. The method of claim 20, wherein said degree of pad glazing is maintained in said first and second polishing phases.

22. The method of claim 20, wherein said first and second polishing phases are performed by using the same polishing pad.

23. The method of claim 20, wherein said predetermined relative speed and down force are applied in said second polishing phase.

24. The method of claim 20, wherein said degree of pad glazing is maintained by controlling a conditioning of a polishing surface of said polishing pad.

25. The method of claim 20, wherein said degree of pad glazing is maintained at approximately 18 percent or higher.
